(19) United States
(12) Patent Application Publication
(10) Pub. No.: US 2013/0173214 A1
(43) Pub. Date: Jul. 4, 2013

(54) METHOD AND STRUCTURE FOR INLINE ELECTRICAL FIN CRITICAL DIMENSION MEASUREMENT

(71) Applicants: Tenko Yamashita, Albany, NY (US); Huiming Bu, Hopewell Junction, NY (US); Effendi Leobandung, Hopewell Junction, NY (US); Theodorus Eduardus Standaert, Hopewell Junction, NY (US)

(72) Inventors: Tenko Yamashita, Albany, NY (US); Huiming Bu, Hopewell Junction, NY (US); Effendi Leobandung, Hopewell Junction, NY (US); Theodorus Eduardus Standaert, Hopewell Junction, NY (US)

(73) Assignee: International Business Machines Corporation, Armonk, NY (US)

(21) Appl. No.: 13/343,186

(22) Filed: Jan. 4, 2012

(51) Int. Cl. G01B 7/02; H01L 23/58; G06F 19/00

(52) U.S. Cl. 702/170; 257/48; 257/E23.002

(57) ABSTRACT

A method and test circuit for electrically measuring the critical dimension of a fin of a FinFET is disclosed. The method comprises measuring the resistance of a first gate test structure, measuring the resistance of a second gate test structure, computing a linear equation relating sheet resistance to gate width, computing a Y intercept value of the linear equation to derive an external resistance value, computing a sheet resistance value for the first gate test structure based on the external resistance value, measuring the resistance of a doped fin test structure, and computing a critical dimension of a fin based on the sheet resistance value.

### FIELD OF THE INVENTION

The present invention relates generally to semiconductor fabrication, and more particularly, to fabrication of FinFET devices.

### BACKGROUND

Field Effect Transistors (FETs) have been the dominant semiconductor technology used to make Application Specific Integrated Circuit (ASIC) chips, microprocessor chips, Static Random Access Memory (SRAM) chips, and the like for many years. In particular, Complementary Metal Oxide Semiconductor (CMOS) technology has dominated the semiconductor process industry for a number of years.

Due to their fast switching times and high current densities, fin field effect transistor (FinFET) devices are a desired device architecture. In its basic form, a FinFET device includes a source, a drain, and one or more fin-shaped channels between the source and the drain. A gate electrode over the fin(s) regulates electron flow between the source and the drain. The architecture of a FinFET device, however, presents notable fabrication challenges. As feature sizes of the devices get increasingly smaller (commensurate with current technology) accurately and consistently fabricating a FinFET becomes challenging. Therefore, it is desirable to have improved methods and structures for FinFET fabrication process monitoring.

### SUMMARY

In one embodiment, a method for electrically measuring the width (critical dimension) of a fin of a FinFET is provided. The method comprises measuring the resistance of a first gate test structure comprising a first doped silicon region on the substrate to obtain a first resistance measurement, measuring the resistance of a second gate test structure comprising a second doped silicon region on the substrate to obtain a second resistance measurement, computing a linear equation relating sheet resistance to gate width based on the first resistance measurement and the second resistance measurement, computing a Y intercept value of the linear equation to derive an external resistance value, computing a sheet resistance value for the first gate test structure based on the external resistance value, measuring the resistance of a doped fin test structure, and computing the width of at least one fin based on the sheet resistance value.

In another embodiment, a FinFET test circuit for electrically measuring the width (critical dimension) of at least one fin of a FinFET is provided. The circuit comprises a plurality of gate test structures, and a doped fin test structure. The plurality of gate test structures and the doped fin test structure are disposed on a substrate, and the width of the gates in the plurality of gate test structures are of at least two different widths.

In yet another embodiment, a FinFET critical dimension test circuit is provided. The circuit comprises a plurality of gate test structures, and a doped fin test structure. The plurality of gate test structures and the doped fin test structure are disposed on a substrate; and each gate test structure comprises a doped silicon region, a gate dielectric layer disposed on the doped silicon region, and a gate disposed on the gate dielectric layer. The doped fin test structure comprises a plurality of doped fins, a dielectric layer disposed over each of the plurality of fins, and a gate disposed over the plurality of fins. The critical dimension for each of the plurality of fins ranges from about 10 nanometers to about 15 nanometers.

### BRIEF DESCRIPTION OF THE DRAWINGS

The structure, operation, and advantages of the present invention will become further apparent upon consideration of the following description taken in conjunction with the accompanying figures (FIGs.). The figures are intended to be illustrative, not limiting.

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures (FIGs) of the drawing, in which case typically the last two significant digits may be the same, the most significant digit being the number of the drawing figure (FIG).

FIGS. 1A and 1B show an example of a gate test structure in accordance with an embodiment of the present invention.

FIGS. 2A-2C show an example of a set of gate test structures in accordance with an embodiment of the present invention.

FIG. 3 is a chart showing the relationship of resistance and gate width.

FIGS. 4A and 4B show an example of a second test structure in accordance with an embodiment of the present invention.

FIG. 5 is a flowchart indicating process steps for an embodiment of the present invention.

FIG. 6 shows a block diagram of an exemplary design flow.

### DETAILED DESCRIPTION

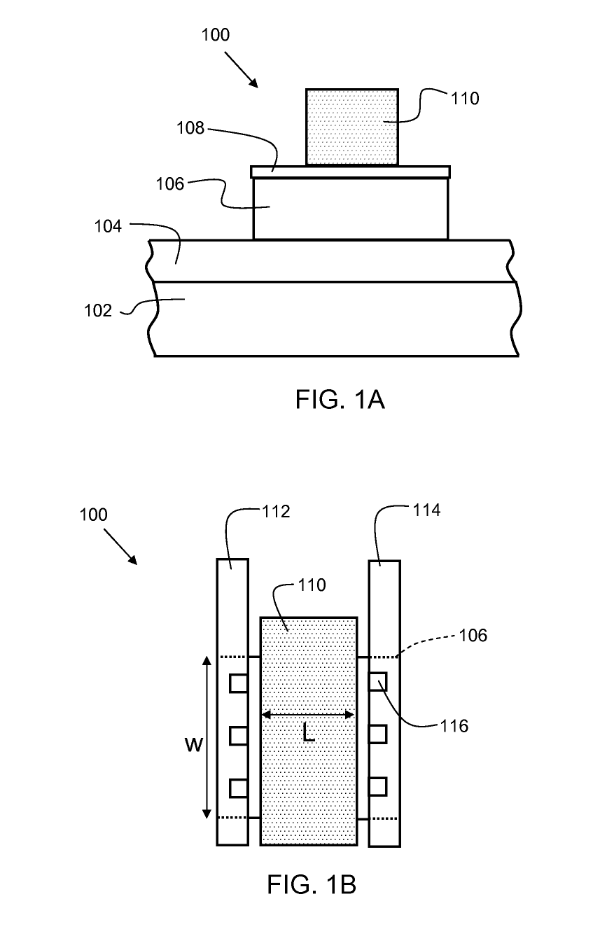

FIGS. 1A and 1B show an example of a gate test structure in accordance with an embodiment of the present invention. FIG. 1A shows a side view of gate test structure 100. A silicon substrate 102 with an insulating layer 104 serves as the base of the test structure 100. In one embodiment, insulating layer 104 is comprised of oxide. A doped silicon region 106 is disposed on the insulating layer 104. In one embodiment, the doped silicon region 106 has a dopant concentration ranging from about 1e19 atoms per cubic centimeter to about 1e20 atoms per cubic centimeter. In one embodiment, the dopant used in the doped silicon region 106 is arsenic. In another embodiment, phosphorous is used. Other dopant species may also be used. Disposed on doped silicon region 106 is gate dielectric layer 108. Gate dielectric layer 108 may be comprised of oxide. Disposed on gate dielectric layer 108 is gate 110. In one embodiment, gate 110 is comprised of polysilicon.

FIG. 1B shows a top-down view of gate test structure 100, as interconnected to metal conduits 112 and 114 by conductive vias, shown generally as 116. Metal conduits 112 and 114 may be part of a metal layer located at a higher layer than the gate test structure 100. The vias 116 may be part of a via layer that interconnects the gate test structure 100 with the metal conduits 112 and 114.

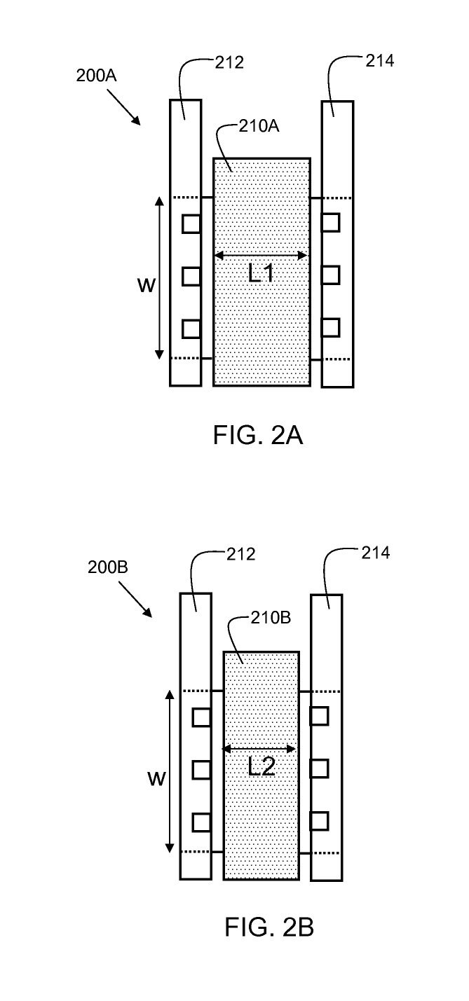

FIGS. 2A-2C show an example of a set of gate test structures in accordance with an embodiment of the present invention. Gate structures 200A, 200B and 200C are similar, except for the gate width L. Gate structure 200A has a gate 210A having a gate width L1. Gate structure 200B has a gate 210B having a gate width L2. Gate structure 200C has a gate 210C having a gate width L3. As shown, L1>L2>L3.

In one embodiment, only gate test structures 200A and 200C are used. Optionally, 3 or more gate test structures may be used. In the case where only two gate test structures are used, gate structure 200A may have a gate width L1 that ranges from about 0.8 micrometers to about 1.5 micrometers, and gate structure 200C may have a gate width L3 that ranges from about 0.3 micrometers to about 0.7 micrometers. Among the gate test structures, there are at least two different gate widths, as to allow deriving the linear equation relating resistance to gate width.

In an embodiment where three test gate structures are used, gate structure 200A may have a gate width L1 that ranges from about 1.4 micrometers to about 1.5 micrometers, gate structure 200B may have a gate width L2 that ranges from about 0.9 micrometers to about 1.1 micrometers, and gate structure 200C may have a gate width L3 that ranges from about 0.4 micrometers to about 0.6 micrometers.

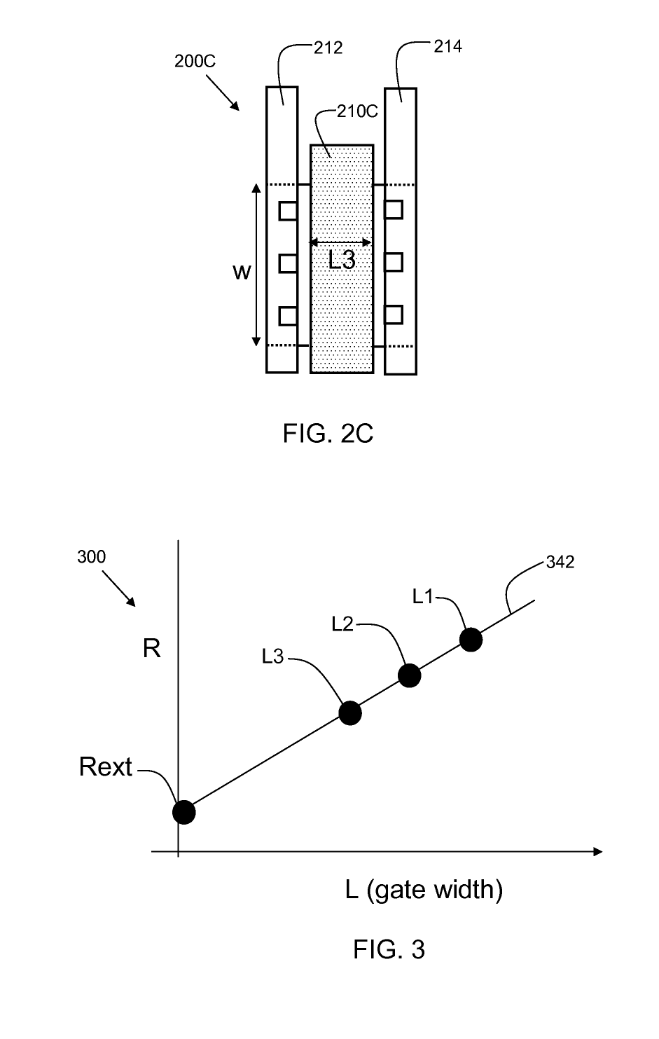

FIG. 3 is a chart 300 showing the relationship of resistance and gate width. The Y (vertical) axis represents measured resistance and the X (horizontal) axis represents gate width (L in FIG. 1B). Each point (L1, L2, L3) on the line 342 represents a resistance measurement of a gate test structure such as 200A, 200B, or 200C. The resistance measurement is made by measuring the resistance between metal conduit 212 and metal conduit 214 in structures 200A, 200B, and 200C.

At a minimum, two measurements may be used to generate two points which define a slope and Y intercept. If more than two measurements are used, a best-fit line may be computed, and the slope and Y intercept of that line may be used to derive Rext, which is the value of the resistance on the vertical axis at the Y-intercept point. This resistance value is the external resistance Rext. Rext represents the theoretical case of a gate of zero width (since L=0 at the Y intercept point). The Rext value represents the resistance due to factors external to the gate.

The sheet resistance ρ of the doped silicon region (106 of FIG. 1A) of the gate test structure is then computed by:

ρ=(Rmeasured−Rext)*W/L, where:

Rmeasured is the measured resistance of one of the gate test structures (e.g. 200A); Rext is the resistance value on the Y intercept of the chart in FIG. 3; W is the width of the doped silicon region (see FIG. 1B); and

L is the width of the gate of the gate test structure (e.g. L1 of).

This sheet resistance value is then used in conjunction with a subsequent measurement on a doped fin test structure to determine the critical dimension (fin thickness) of the fin.

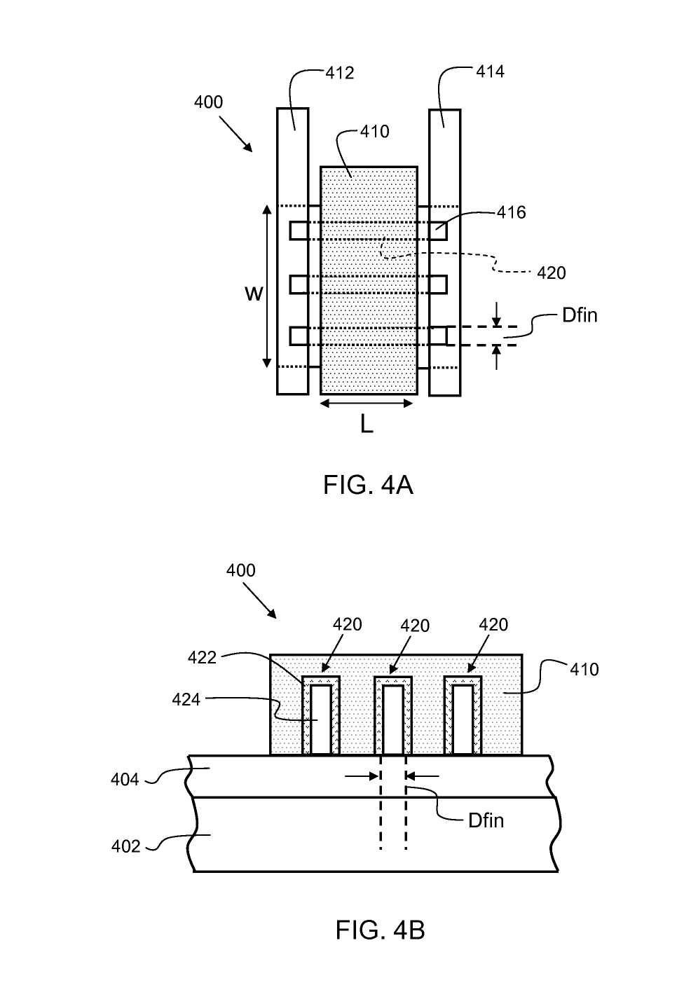

FIGS. 4A and 4B show an example of a doped fin test structure in accordance with an embodiment of the present invention. FIG. 4A shows a top-down view of doped fin test structure 400. Doped fin test structure 400 is similar to gate test structure 100, with a primary difference being a plurality of fins (shown generally as 420) which traverse the width of gate 410. Metal conduits 412 and 414 are the points between which the resistance is measured. A plurality of vias 416 connect the metal conduits 412 and 414 to the fins 420. The critical dimension Dfin represents the thickness of the fin.

FIG. 4B shows a side view of doped fin test structure 400, with the metal conduits and vias not shown. As shown in FIG. 4B, the doped fin test structure 400 is disposed on insulating layer 404 which is disposed on silicon substrate 402. Each fin 420 is comprised of a doped silicon portion 424, which is disposed on the insulating layer 404. On the top and sides of the doped silicon portion 424 is a dielectric layer 422. The dielectric layer may be comprised of oxide. While the doped fin test structure 400 of FIG. 4B has 3 fins 420, other embodiments may have more fins. In one embodiment, the doped fin test structure may have 3 to 25 fins. The critical dimension Dfin represents the thickness of the fin. In one embodiment, the fins 420 have a Dfin ranging from about 10 nanometers to about 15 nanometers. The Dfin value is calculated as:

Dfin=ρ*L/(n*Rmeasured), where:

ρ is the sheet resistance previously calculated;
L is the width of the gate;
n is the number of fins;
Rmeasured is the resistance measured between metal conduit 412 and metal conduit 414 (see FIG. 4A).

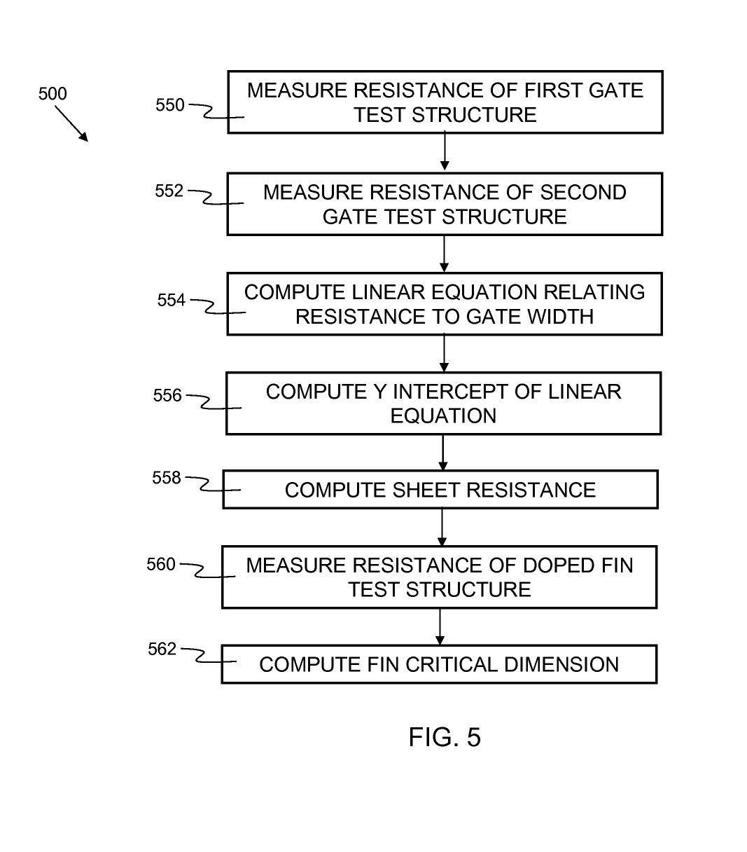

FIG. 5 is a flowchart 500 indicating process steps for an embodiment of the present invention. In process step 550, the resistance of a first gate test structure is measured (e.g. 200A of FIG. 2A). In process step 552, the resistance of a second gate test structure is measured (e.g. 200C of FIG. 2C). In process step 554, a linear equation is computed which relates resistance to gate width. A minimum of two measurements are needed to define a line with a slope and Y intercept using common algebraic techniques. Optionally, resistance measurements may be made on additional gate test structures of varying gate width to obtain multiple points. These points may then be used to compute a best-fit line using standard regression techniques. In process step 556, the Y intercept of the linear equation is computed, which yields the external resistance (Rext of FIG. 3). In process step 558, the sheet resistance of the doped silicon material is computed by the following formula:

ρ=(Rmeasured−Rext)*W/L.

In process step 560, the resistance of the doped fin test structure is measured. This is performed by measuring the resistance between metal conduit 412 and metal conduit 414 (see FIG. 4A). In process step 562, the fin critical dimension (see Dfin, FIG. 4A and FIG. 4B) is computed by the following formula:

Dfin=ρ*L/(n*Rmeasured).

Thus, embodiments of the present invention provide a method and corresponding test structures for measuring the fin width (critical dimension) via an electrical measurement. A FinFET critical dimension test circuit comprised of multiple gate test structures and a doped fin test structure are disposed on an integrated circuit. The test circuit is not part of the functional circuitry of an IC (integrated circuit) chip, but exists for the purposes of inline monitoring of the FinFET critical dimension.

This is well-suited for inline measurement and process monitoring. As the fin dimension is an important aspect of FinFET fabrication, the ability to monitor the process with a series of fast, inline resistance measurements provides advantages that can lead to improved yield and reduced variation amongst similar fabricated devices.

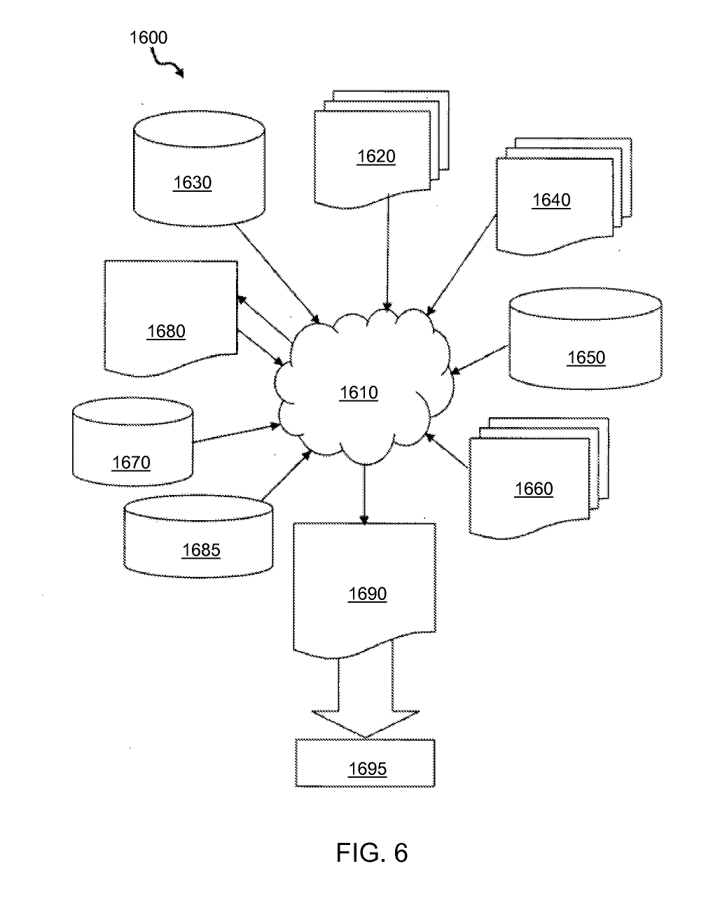

FIG. 6 shows a block diagram of an exemplary design flow 1600 used for example, in semiconductor IC logic design, simulation, test, layout, and manufacture. Design flow 1600 includes processes, machines and/or mechanisms for processing design structures or devices to generate logically or otherwise functionally equivalent representations of the design structures and/or devices described above and shown in FIGS. 1-5. The design structures processed and/or generated by design flow 1600 may be encoded on machine-readable transmission or storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array).

Design flow 1600 may vary depending on the type of representation being designed. For example, a design flow 1600 for building an application specific IC (ASIC) may differ from a design flow 1600 for designing a standard component or from a design flow 1600 for instantiating the design into a programmable array, for example a programmable gate array (PGA) or a field programmable gate array (FPGA) offered by Altera® Inc. or Xilinx® Inc. FIG. 6 illustrates multiple such design structures including an input design structure 1620 that is preferably processed by a design process 1610. Design structure 1620 may be a logical simulation design structure generated and processed by design process 1610 to produce a logically equivalent functional representation of a hardware device. Design structure 1620 may also or alternatively comprise data and/or program instructions that when processed by design process 1610, generate a functional representation of the physical structure of a hardware device. Whether representing functional and/or structural design features, design structure 1620 may be generated using electronic computer-aided design (ECAD) such as implemented by a core developer/designer. When encoded on a machine-readable data transmission, gate array, or storage medium, design structure 1620 may be accessed and processed by one or more hardware and/or software modules within design process 1610 to simulate or otherwise functionally represent an electronic component, circuit, electronic or logic module, apparatus, device, or system such as those shown in FIGS. 1-5. As such, design structure 1620 may comprise files or other data structures including human and/or machine-readable source code, compiled structures, and computer-executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher level design languages such as C or C++.

Design process 1610 preferably employs and incorporates hardware and/or software modules for synthesizing, translating, or otherwise processing a design/simulation functional equivalent of the components, circuits, devices, or logic structures shown in FIGS. 1-5 to generate a Netlist 1680 which may contain design structures such as design structure 1620. Netlist 1680 may comprise, for example, compiled or otherwise processed data structures representing a list of wires, discrete components, logic gates, control circuits, I/O devices, models, etc. that describes the connections to other elements and circuits in an integrated circuit design. Netlist 1680 may be synthesized using an iterative process in which netlist 1680 is resynthesized one or more times depending on design specifications and parameters for the device. As with other design structure types described herein, netlist 1680 may be recorded on a machine-readable data storage medium or programmed into a programmable gate array. The medium may be a non-volatile storage medium such as a magnetic or optical disk drive, a programmable gate array, a compact flash, or other flash memory. Additionally, or in the alternative, the medium may be a system or cache memory, buffer space, or electrically or optically conductive devices and materials on which data packets may be transmitted and intermediately stored via the Internet, or other networking suitable means.

Design process 1610 may include using a variety of inputs; for example, inputs from library elements 1630 which may house a set of commonly used elements, circuits, and devices, including models, layouts, and symbolic representations, for a given manufacturing technology (e.g., different technology nodes, 32 nm, 45 nm, 90 nm, etc.), design specifications 1640, characterization data 1650, verification data 1660, design rules 1670, and test data files 1685 (which may include test patterns and other testing information). Design process 1610 may further include, for example, standard circuit design processes such as timing analysis, verification, design rule checking, place and route operations, etc. One of ordinary skill in the art of integrated circuit design can appreciate the extent of possible electronic design automation tools and applications used in design process 1610 without deviating from the scope and spirit of the invention. The design structure of the invention is not limited to any specific design flow.

Design process 1610 preferably translates an embodiment of the invention as shown in FIGS. 1-5, along with any additional integrated circuit design or data (if applicable), into a second design structure 1690. Design structure 1690 resides on a storage medium in a data format used for the exchange of layout data of integrated circuits (e.g. information stored in a GDSII (GDS2), GL1, OASIS, or any other suitable format for storing such design structures). Design structure 1690 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as described above with reference to FIGS. 1-5. Design structure 1690 may then proceed to a stage 1695 where, for example, design structure 1690: proceeds to tape-out, is released to manufacturing, is released to a mask house, is sent to another design house, is sent back to the customer, etc.

Although the invention has been shown and described with respect to a certain preferred embodiment or embodiments, certain equivalent alterations and modifications will occur to others skilled in the art upon the reading and understanding of this specification and the annexed drawings. In particular regard to the various functions performed by the above described components (assemblies, devices, circuits, etc.) the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more features of the other embodiments as may be desired and advantageous for any given or particular application.

What is claimed is:

1. A method for electrically measuring the width of at least one fin of a FinFET disposed on a substrate, comprising:
measuring the resistance of a first gate test structure comprising a first doped silicon region on the substrate to obtain a first resistance measurement;
measuring the resistance of a second gate test structure comprising a second doped silicon region on the substrate to obtain a second resistance measurement;
computing a linear equation relating resistance to gate width based on the first resistance measurement and the second resistance measurement;
computing a Y intercept value of the linear equation to derive an external resistance value;
computing a sheet resistance value for the first gate test structure based on the external resistance value;
measuring the resistance of a doped fin test structure; and
computing the width of at least one fin based on the sheet resistance value.

2. The method of claim 1, further comprising:
measuring the resistance of a third gate test structure comprising a third doped silicon region on the substrate to obtain a third resistance measurement.

3. The method of claim 2, wherein computing a linear equation relating resistance to gate width comprises computing a best fit line of the measurements of the first, second, and third gate test structures.

4. The method of claim 1, wherein computing the width of at least one fin based on the sheet resistance value comprises multiplying the sheet resistance value by the gate width divided by the product of the number of fins and the measured resistance of the doped fin test structure.

5. The method of claim 1, wherein computing a sheet resistance value for the first gate test structure based on the external resistance value comprises:
subtracting the external resistance from the measured resistance to derive an internal resistance; and
multiplying the internal resistance by the length of the doped silicon region of the first gate test structure divided by the width of the gate of the first gate test structure.

6. The method of claim 1, wherein:
measuring the resistance of a first gate test structure comprises measuring the resistance of a gate test structure having a gate width ranging from about 0.3 micrometers to about 0.7 micrometers; and wherein
measuring the resistance of a second gate test structure comprises measuring the resistance of a gate test structure having a gate width ranging from about 0.8 micrometers to about 1.5 micrometers.

7. A FinFET test circuit for electrically measuring the width of at least one fin of a FinFET, comprising:
a plurality of gate test structures; and
a doped fin test structure; wherein
the plurality of gate test structures and the doped fin test structure are disposed on a substrate, wherein the width of the gates in the plurality of gate test structures are of at least two different widths.

8. The test circuit of claim 7, wherein each gate test structure comprises:
a doped silicon region;
a gate dielectric layer disposed on the doped silicon region; and
a gate disposed on the gate dielectric layer.

9. The test circuit of claim 8, wherein the doped fin test structure comprises:
a plurality of doped fins;
a dielectric layer disposed over each of the plurality of doped fins; and
a gate disposed over the plurality of doped fins.

10. The test circuit of claim 9, wherein the doped silicon region is doped with a dopant concentration ranging from about 1e19 atoms per cubic centimeter to about 1e20 atoms per cubic centimeter.

11. The test circuit of claim 9, wherein the doped fins are doped with a dopant concentration ranging from about 1e19 atoms per cubic centimeter to about 1e20 atoms per cubic centimeter.

12. The test circuit of claim 10, wherein the doped silicon region is doped with arsenic.

13. The test circuit of claim 10, wherein the doped silicon region is doped with phosphorous.

14. The test circuit of claim 10, wherein the doped fins are doped with arsenic.

15. The test circuit of claim 10, wherein the doped fins are doped with phosphorous.

16. The test circuit of claim 8, wherein the gate of each gate test structure is comprised of polysilicon.

17. A FinFET critical dimension test circuit comprising:
a plurality of gate test structures; and
a doped fin test structure; wherein
the plurality of gate test structures and the doped fin test structure are disposed on a substrate; and wherein each gate test structure comprises:
a doped silicon region;
a gate dielectric layer disposed on the doped silicon region; and
a gate disposed on the gate dielectric layer; and wherein the doped fin test structure comprises:
a plurality of doped fins;
a dielectric layer disposed over each of the plurality of fins; and
a gate disposed over the plurality of fins; and wherein the critical dimension for each of the plurality of fins ranges from about 10 nanometers to about 15 nanometers.

18. The test circuit of claim 17, wherein the plurality of doped fins comprises 3 to 25 fins.

19. The test circuit of claim 17, wherein the plurality of gate test structures comprises a first gate test structure and a second gate test structure, and wherein the first gate test structure has a gate width ranging from about 0.3 micrometers to about 0.7 micrometers, and wherein the second gate test structure has a gate width ranging from about 0.8 micrometers to about 1.5 micrometers.

20. The test circuit of claim 19, wherein the plurality of gate test structures further comprises a third gate test structure, and wherein the first gate test structure has a gate width ranging from about 0.4 micrometers to about 0.6 micrometers, and wherein the second gate test structure has a gate width ranging from about 1.4 micrometers to about 1.5 micrometers; and wherein the third gate test structure has a gate width ranging from about 0.9 micrometers to about 1.1 micrometers.
